(19) United States
(12) Patent Application Publication
(10) Pub. No.: US 2006/0209621 A1
(43) Pub. Date: Sep. 21, 2006

(54) Optical disk recording/reproducing apparatus

(76) Inventors: Hitoshi Andoh, Situkawa (JP); Naoki Yumiyama, Kitakumecho (JP)

Correspondence Address: STEPTOE & JOHNSON LLP, 1330 CONNECTICUT AVENUE, N.W., WASHINGTON, DC, 20036, US

(21) Appl. No.: 10/548,181

(22) PCT Filed: Mar. 17, 2004
(86) PCT No.: PCT/JP04/03600

§ 371 Date: Sep. 7, 2005

(30) Foreign Application Priority Data
Mar. 20, 2003 (JP) 2003076684

(51) Int. Cl. G11C 13/04

(52) U.S. Cl. 365/234

(57) ABSTRACT

An optical disc recording/reproducing apparatus is provided which can obtain the best recording quality. Data is recorded while tracking is displaced by gradually supplying an offset voltage (deviation value) to a tracking error signal, and then reproduction is performed on a recording area. The jitter value (reading state of address information) of biphase data generated from a reproduction RF signal is detected by a biphase jitter detector (20). Further, on the basis of the offset voltage value (tracking deviation) supplied to the tracking error signal and the detected jitter value of the biphase data, a CPU (14) determines an offset voltage value where the biphase data has the minimum jitter value, as a tracking deviation for obtaining the best reading state of data, and records the offset voltage value in memory (15).

### TECHNICAL FIELD

The present invention relates to an optical disc recording/reproducing apparatus for recording and reproducing data on a recordable optical disc such as a CD-R/RW and a DVD.

### BACKGROUND ART

A detrack tolerance value indicating a tolerance of a tracking deviation is one of factors indicating the reproduction capability of an optical disc reproducing apparatus for reproducing an optical disc where data is recorded.

A conventional detrack tolerance detector for detecting a detrack tolerance value detects a reproduction state of a disc while gradually adding a deviation value to a tracking error signal to displace tracking during the reproduction of the disc, so that a detrack tolerance value is detected which indicates the reproduction capability of the optical disc reproducing apparatus. To be specific, an offset voltage is gradually added to the tracking error signal as a deviation value during the reproduction of the disc, and an error value of address data generated from a reproduction RF signal is detected as a reproduction state of the disc while the center voltage of the tracking error signal is shifted. A detrack tolerance value indicating the reproduction capability of the optical disc reproducing apparatus is detected according to a voltage shifted from the original center voltage when the address error value exceeds a predetermined value. In this way, the conventional detrack tolerance detector detects a detrack tolerance value (e.g., see Japanese Patent Laid-Open No. 08-249685). The conventional detrack tolerance detector will be described in detail below.

FIG. 2 is a block diagram schematically showing the configuration of a MiniDisc (registered trademark) player using the conventional detrack tolerance detector. In FIG. 2, an optical head 31 comprises an optical system which includes a laser diode for emitting laser light, a polarization beam splitter, and an object lens, a light detector for detecting light reflected from an optical disc 30, and a biaxial device for moving the object lens in the radius direction (tracking direction) of the disc and in the contacting/separating direction (focus direction) with respect to the disc.

An RF amplifier 32 generates a reproduction RF signal, a tracking error signal, a focus error signal, and so on by arithmetic process from the output of the light detector included in the optical head 31, and the RF amplifier 32 outputs the signals to a digital servo circuit 33. The digital servo circuit 33 generates an FCS (Focusing Servo)—PWM signal and a TRK (Tracking Servo)—PWM signal from the focus error signal and the tracking error signal, supplies the signals to an FCK coil and a TRK coil of the biaxial device via a servo driver 34, and performs focus control and tracking control.

FIG. 3 is a block diagram showing the detail of circuits of the RF amplifier and so on shown in FIG. 2.

In FIG. 3, reference numerals 31A to 31F denote photodetectors serving as light detectors. Among the photodetectors, the photodetectors 31E and 31F are photodetectors for generating tracking error signals.

Further, a part surrounded by a dotted line indicates the RF amplifier 32, which is constituted of operational amplifiers 36A to 36F for converting currents outputted by the photodetectors 31A to 31F into voltages, and operational amplifiers 37A to 37C for performing arithmetic computations on the outputs of the operational amplifiers 36A to 36F. The operational amplifiers 36E and 36F and the operational amplifier 37C of these amplifiers are provided for generating tracking error signals. The operational amplifiers 36E and 36F convert currents SE and SF outputted from the photodetectors 31E and 31F into voltages. The operational amplifier 37C determines a difference between the voltages SE and SF (SE−SF) and outputs the difference as the focus error signal to the digital servo circuit 33.

A gain adjustment circuit 39 for shifting the center voltage of the tracking error signal is provided on one of the operational amplifiers 36E and 36F for converting the currents SE and SF, which are outputted from the photodetectors 31E and 31F, into voltages. The gain adjustment circuit 39 changes the gain of the operational amplifier according to a detrack signal (PWM signal) which is supplied from a system controller 35 via a lowpass filter 38. Thus, one of the operational amplifiers 36E and 36F can be changed in gain from the other, thereby shifting the center voltage of the tracking error signal by a gain difference.

The following will describe the detection processing of detrack tolerance in the MiniDisc player configured as shown in FIGS. 2 and 3.

First, the center voltage of the tracking error signal is set at a voltage value Vc so as to position a light spot at the track center. Then, an offset voltage (deviation value) is added to the tracking error signal by controlling the gain adjustment circuit 39 and the center voltage is increased by one step Va. As shown in FIGS. 4(A) to 4(C), the tracking error signal is biased every time the center voltage increases by one step Va. By shifting the center voltage thus, the tracking position is displaced from the track center and an error value of address data generated from the reproduction RF signal is detected. As a result of displacing tracking, when an address error value exceeds a predetermined value, a shifted voltage value Vmax from the original center voltage value Vc is captured.

Similarly, the center voltage is reduced by one step Va by controlling the gain adjustment circuit 39. As shown in FIGS. 5(A) to 5(C), the tracking error signal is biased every time the center voltage is reduced by one step Va. By shifting the center voltage thus, the tracking position is displaced from the track center and an error value of address data generated from the reproduction RF signal is detected. As a result of displacing tracking, when an address error value exceeds the predetermined value, a shifted voltage value Vmin from the original center voltage value Vc is captured.

With this processing, the shift voltage values Vmax and Vmin are determined which are shifted from the original center voltage value Vc serving as the reproduction limit. A detrack tolerance value indicating the reproduction capability of the optical disc reproducing apparatus is derived from the shifted voltage values Vmax and Vmin.

FIG. 6 shows an example of the relationship between a detrack value [am] indicating a deviation distance from the track center and an address error value indicating a reproduction state of the disc. As shown in FIG. 6, when the detrack value exceeds, e.g., ±0.2 μm, the address error value starts rapidly increasing. In the case of such a relationship, the detrack tolerance value (detrack value serving as the reproduction limit) is, e.g., ±0.2 μm. The detrack value can be determined by a voltage value shifted from the original center voltage value Vc.

On the other hand, when this technique is used to increase the reproduction capability of the optical disc reproducing apparatus, the detrack tolerance value [μm] is determined in the above-described manner and a voltage value Vcenter is determined which is shifted from the original center voltage value Vc and corresponds to an intermediate detrack value [μm]. Then, the determined shifted voltage value Vcenter is added to the tracking error signal to perform reproduction. Thus, it is possible to perform reproduction while obtaining a read margin relative to the detrack tolerance value serving as the reproduction limit.

However, when reproduction is performed while the shifted voltage value Vcenter determined thus is added to the tracking error signal, the following problem arises:

The dotted line of FIG. 7 indicates the relationship among a detrack value, a jitter value (reading state of data) of data obtained by binarizing a reproduction RF signal (e.g., an EFM signal and an 8-16 modulation signal), a jitter value (reading state of address information) of address data obtained by binarizing an ATIP (Absolute Time In Pre-groove) signal having been recorded as address information on an optical disc, and so on. As indicated by the dotted line, the relationship between the detrack value and the jitter value does not always change symmetrically with respect to an axis due to variations in the manufacturing of the optical disc reproducing apparatus and the biased characteristics of circuits constituting the apparatus. An asymmetrical change is shown rather than a symmetrical change. For example, in the optical disc reproducing apparatus where the relationship between the detrack value and the jitter value is characterized as the dotted line shown in FIG. 7, when the detrack value is ±0.1 μm, the jitter value is minimized, that is, the reproduction capability is optimized.

Meanwhile, the reproduction RF signal is error corrected after binarization. Therefore, even when the reproduction RF signal has somewhat poor quality, that is, even when data has a somewhat large jitter value, the reproduction capability is improved by error correction.

For this reason, even in the case of the optical disc reproducing apparatus where the relationship between the detrack value and the jitter is characterized as the dotted line of FIG. 7, the relationship between the detrack value and the address error value after error correction is characterized as the solid line of FIG. 7. In this case, the address error value does not change when the detrack value is within ±0.2 μm. Thus, in order to perform reproduction while obtaining a read margin relative to the detrack tolerance value serving as the reproduction limit, reproduction is performed while the shifted voltage value Vcenter, which corresponds to the intermediate detrack value (0 μm) of the detrack tolerance value (±0.2 μm), is added to the tracking error signal.

However, even when tracking is controlled while the shifted voltage value Vcenter determined thus is added to the tracking error signal, in the case of reproduction capability degraded by, e.g., the influence of temperature characteristics or the like of circuits or devices, the following problem arises:

In contrast to the dotted line of FIG. 7, a chain line shows the relationship between the detrack value and the jitter value when the reproduction capability is degraded thus by the influence of the temperature characteristics or the like of circuits or devices. When the reproduction capability is degraded, the jitter value of data (reading state of data and address information) exceeds the reproduction limit at 0 μm as indicated by the chain line of FIG. 7. That is, when reproduction is performed using the detrack value derived in the conventional manner, a read margin decreases due to the influence of a change in the environment or the like, resulting in a read error.

Further, the quality of the reproduction RF signal, that is, the jitter value of data is affected by recording quality as well as the degraded reproduction capability. This suggests the following description:

The dotted line of FIG. 8 shows how a jitter value changes when a recorded disc is reproduced while a light spot of laser light is gradually displaced in the track direction (radius direction). Further, the solid line of FIG. 8 shows how a jitter value changes when a light spot is caused to track, e.g., the track center to perform reproduction on a recording area. The reproduction is performed after data is recorded on an unrecorded disc while the light spot is gradually displaced in the track direction. As is evident from FIG. 8, a detrack value for obtaining the best recording quality and a detrack value for obtaining the best reproduction state are not equal to each other. When recording is performed using a detrack value (±0.1 μm) for obtaining the best reproduction capability, the recording quality is degraded as compared with recording using a detrack value of −0.2 μm. Consequently, in order to improve the recording quality, it is necessary to add the shifted voltage value Vcenter, which corresponds to the detrack value (−0.2 μm), to the tracking error signal.

As described above, the detrack value for obtaining the best recording quality and the detrack value for obtaining the best reproduction state are not equal to each other. When recording is performed using the detrack value for obtaining the best reproduction state, the best recording quality cannot be obtained. The same problem is found in the characteristics of focus and tilt as well as detrack.

In consideration of the problems, in the present invention, data is recorded while tracking is displaced by gradually adding a deviation value to a tracking error signal, and then reproduction is performed on a recording area. A reading state of data, a reading state of address information, or an amplitude value of a reproduction signal is detected as information indicating recording quality. A tracking deviation for obtaining the best reading state of data, a tracking deviation for obtaining the best reading state of address information, or a tracking deviation for obtaining the maximum amplitude value of a reproduction signal is determined. An object is to provide an optical disc recording/reproducing apparatus which can obtain the best recording quality during data recording by displacing tracking by one of the tracking deviations or an optimum tracking deviation obtained on the basis of the tracking deviations.

Further, data is recorded while a focus is displaced from a focus point by gradually adding a deviation value to a focus error signal, and then reproduction is performed on a recording area. A reading state of data, a reading state of address information, or an amplitude value of a reproduction signal is detected as information indicating recording quality. A deviation from the focus point with the best reading state of data, a deviation from the focus point with the best reading state of address information, or a deviation from the focus point with the maximum amplitude value of the reproduction signal is determined. An object is to provide an optical disc recording/reproducing apparatus which can obtain the best recording quality during data recording by displacing the focus from the focus point by one of the deviations or an optimum deviation from the focus point. The optimum deviation is obtained on the basis of the deviations.

Moreover, data is recorded while an inclination angle (tilt angle) of an optical axis of light is gradually displaced with respect to a surface of an optical disc, and then reproduction is performed on a recording area. A reading state of data, a reading state of address information, or an amplitude value of a reproduction signal is detected as information indicating recording quality. A tilt angle for obtaining the best reading state of data, a tilt angle for obtaining the best reading state of address information, or a tilt angle for obtaining the maximum amplitude value of the reproduction signal is determined. An object is to provide an optical disc recording/reproducing apparatus which can obtain the best recording quality during data recording by inclining the optical axis by one of the tilt angles or an optimum tilt angle obtained on the basis of the tilt angles.

### DISCLOSURE OF THE INVENTION

An optical disc recording/reproducing apparatus according to claim 1 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting a reading state of address information from the reproduction signal having been generated by reproduction on a recording area, and a unit for determining and recording a tracking deviation for obtaining the best reading state of address information, the tracking deviation being determined on the basis of the relationship between the detected reading state of address information and a tracking deviation when data is recorded while tracking is displaced, wherein data is recorded while tracking is displaced by the recorded tracking deviation.

An optical disc recording/reproducing apparatus according to claim 2 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting a reading state of data from the reproduction signal having been generated by reproduction on a recording area, and a unit for determining and recording a tracking deviation for obtaining the best reading state of data, the tracking deviation being determined on the basis of the relationship between the detected reading state of data and a tracking deviation when data is recorded while tracking is displaced, wherein data is recorded while tracking is displaced by the recorded tracking deviation.

An optical disc recording/reproducing apparatus according to claim 3 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting an amplitude value of the reproduction signal having been generated by reproduction on a recording area, and a unit for determining and recording a tracking deviation for obtaining the maximum amplitude value of the reproduction signal, the tracking deviation being determined on the basis of the relationship between the detected amplitude value of the reproduction signal and a tracking deviation when data is recorded while tracking is displaced, wherein data is recorded while tracking is displaced by the recorded tracking deviation.

An optical disc recording/reproducing apparatus according to claim 4 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting a reading state of address information from the reproduction signal having been generated by reproduction on a recording area, a unit for recording data while displacing tracking, and detecting a reading state of data from the reproduction signal having been generated by reproduction on the recording area, and a unit for determining a tracking deviation for obtaining the best reading state of address information and a tracking deviation for obtaining the best reading state of data, the tracking deviations being determined on the basis of the relationship among the detected reading state of address information, the detected reading state of data, and a tracking deviation when data is recorded while tracking is displaced, the unit determining and recording an optimum tracking deviation for recording on the basis of the deviations, wherein data is recorded while tracking is displaced by the recorded tracking deviation.

An optical disc recording/reproducing apparatus according to claim 5 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting a reading state of data from the reproduction signal having been generated by reproduction on a recording area, a unit for recording data while displacing tracking, and detecting an amplitude value of the reproduction signal having been generated by reproduction on the recording area, and a unit for determining a tracking deviation for obtaining the best, reading state of data and a tracking deviation for obtaining the maximum amplitude value of the reproduction signal, the tracking deviations being determined on the basis of the relationship among the detected reading state of data, the detected amplitude value of the reproduction signal, and a tracking deviation when data is recorded while tracking is displaced, the unit determining and recording an optimum tracking deviation for recording on the basis of the deviations, wherein data is recorded while tracking is displaced by the recorded tracking deviation.

An optical disc recording/reproducing apparatus according to claim 6 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for recording data while displacing tracking, and detecting a reading state of address information from the reproduction signal having been generated by reproduction on a recording area, a unit for recording data while displacing tracking, and detecting an amplitude value of the reproduction signal having been generated by reproduction on the recording area, and a unit for determining a tracking deviation for obtaining the best reading state of address information and a tracking deviation for obtaining the maximum amplitude value of the reproduction signal, the tracking deviations being determined on the basis of the relationship among the detected reading state of address information, the detected amplitude value of the reproduction signal, and a tracking deviation when data is recorded while tracking is displaced, the unit determining and recording an optimum tracking deviation for recording on the basis of the deviations, wherein data is recorded while tracking is displaced by the recorded tracking deviation.

An optical disc recording/reproducing apparatus according to claim 7 of the present invention, comprising an optical pickup for emitting light on a track of an optical disc on which address information is recorded beforehand, and outputting a signal according to light reflected from the optical disc, and a signal generating unit for generating a reproduction signal and a tracking error signal on the basis of the output of the optical pickup, the tracking error signal corresponding to a tracking deviation, the optical disc recording/reproducing apparatus performing tracking according to the tracking error signal to record and reproduce data, wherein the apparatus further comprises a unit for displacing tracking by supplying a deviation value to the tracking error signal, a unit for detecting a reading state of address information from the reproduction signal having been generated by light reflected from the optical disc when data is recorded with displaced tracking, and a unit for determining and recording a tracking deviation for obtaining the best reading state of address information, the tracking deviation being determined on the basis of the relationship between the detected reading state of address information and a tracking deviation when data is recorded while tracking is displaced, wherein data is recorded while tracking is displaced by the recorded tracking deviation.

An optical disc recording/reproducing apparatus according to claim 8 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting a reading state of address information from the reproduction signal having been generated by reproduction on a recording area, a unit for determining and recording a deviation from the focus point with the best reading state of address information, the deviation being determined on the basis of the relationship between the detected reading state of address information and a deviation from the focus point when the data is recorded while the focus of light is displaced from the focus point, wherein data is recorded while the focus of light is displaced from the focus point by the recorded deviation from the focus point.

An optical disc recording/reproducing apparatus according to claim 9 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting a reading state of data from the reproduction signal having been generated by reproduction on a recording area, and a unit for determining and recording a deviation from the focus point with the best reading state of data, the deviation being determined on the basis of the relationship between the detected reading state of data and the deviation from the focus point when data is recorded while the focus of light is displaced from the focus point, wherein data is recorded while the focus of light is displaced from the focus point by the recorded deviation from the focus point.

An optical disc recording/reproducing apparatus according to claim 10 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting an amplitude value of the reproduction signal having been generated by reproduction on a recording area, and a unit for determining and recording a deviation from the focus point with the maximum amplitude value of the reproduction signal, the deviation being determined on the basis of the relationship between the detected amplitude value of the reproduction signal and the deviation from the focus point when data is recorded while the focus of light is displaced from the focus point, wherein data is recorded while the focus of light is displaced from the focus point by the recorded deviation from the focus point.

An optical disc recording/reproducing apparatus according to claim 11 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting a reading state of address information from the reproduction signal having been generated by reproduction on a recording area, a unit for recording data while displacing the focus of light from the focus point, and detecting a reading state of data from the reproduction signal having been generated by reproduction on the recording area, and a unit for determining a deviation from the focus point with the best reading state of address information and a deviation from the focus point with the best reading state of data, the tracking deviations being determined on the basis of the relationship among the detected reading state of address information, the detected reading state of data, and a deviation from the focus point when data is recorded while the focus of light is displaced from the focus point, the unit determining and recording an optimum deviation for recording from the focus point on the basis of the deviations, wherein data is recorded while the focus of light is displaced from the focus point by the recorded deviation from the focus point.

An optical disc recording/reproducing apparatus according to claim 12 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting a reading state of data from the reproduction signal having been generated by reproduction on a recording area, a unit for recording data while displacing the focus of light from the focus point, and detecting an amplitude value of the reproduction signal having been generated by reproduction on the recording area, and a unit for determining a deviation from the focus point with the best reading state of data and a deviation from the focus point with the maximum amplitude value of the reproduction signal, the tracking deviations being determined on the basis of the relationship among the detected reading state of data, the detected amplitude value of the reproduction signal, and a deviation from the focus point when data is recorded while the focus of light is displaced from the focus point, the unit determining and recording an optimum deviation for recording from the focus point on the basis of the deviations, wherein data is recorded while the focus of light is displaced from the focus point by the recorded deviation from the focus point.

An optical disc recording/reproducing apparatus according to claim 13 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for recording data while displacing the focus of light from the focus point, and detecting a reading state of address information from the reproduction signal having been generated by reproduction on a recording area, a unit for recording data while displacing the focus of light from the focus point, and detecting an amplitude value of the reproduction signal having been generated by reproduction on the recording area, and a unit for determining a deviation from the focus point with the best reading state of address information and a deviation from the focus point with the maximum amplitude value of the reproduction signal, the tracking deviations being determined on the basis of the relationship among the detected reading state of data, the detected amplitude value of the reproduction signal, and a deviation from the focus point when data is recorded while the focus of light is displaced from the focus point, the unit determining and recording an optimum deviation for recording from the focus point on the basis of the deviations, wherein data is recorded while the focus of light is displaced from the focus point by the recorded deviation from the focus point.

An optical disc recording/reproducing apparatus according to claim 14 of the present invention, comprising an optical pickup for emitting light on a track of an optical disc on which address information is recorded beforehand, and outputting a signal according to light reflected from the optical disc, and a signal generating unit for generating a reproduction signal and a focus error signal on the basis of the output of the optical pickup, the focus error signal corresponding to a deviation of the focus of emitted light from a focus point, the optical disc recording/reproducing apparatus aligning the focus of light with the focus point according to the focus error signal to record and reproduce data, wherein the apparatus further comprises a unit for displacing the focus of light from the focus point by supplying a deviation value to the focus error signal, a unit for detecting a reading state of address information from the reproduction signal having been generated by light reflected from the optical disc when data is recorded while the focus of light is displaced from the focus point, and a unit for determining and recording a deviation from the focus point with the best reading state of address information, the deviation being determined on the basis of the relationship between the detected reading state of address information and a deviation from the focus point when data is recorded while the focus of light is displaced from the focus point, wherein data is recorded while the focus of light is displaced from the focus point by the recorded deviation from the focus point.

An optical disc recording/reproducing apparatus according to claim 15 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting a reading state of address information from the reproduction signal having been generated by reproduction on a recording area, and a unit for determining and recording an inclination angle for obtaining the best reading state of address information, the inclination angle being determined on the basis of the relationship between the detected reading state of address information and the inclination angle when data is recorded while the inclination angle of the optical axis of light is displaced with respect to the surface of the optical disc, wherein data is recorded while the optical axis of light is inclined by the recorded inclination angle.

An optical disc recording/reproducing apparatus according to claim 16 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting a reading state of data from the reproduction signal having been generated by reproduction on a recording area, and a unit for determining and recording an inclination angle for obtaining the best reading state of data, the inclination angle being determined on the basis of the relationship between the detected reading state of data and an inclination angle when data is recorded while the inclination angle of the optical axis of light is displaced with respect to the surface of the optical disc, wherein data is recorded while the optical axis of light is inclined by the recorded inclination angle.

An optical disc recording/reproducing apparatus according to claim 17 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting an amplitude value of the reproduction signal having been generated by reproduction on a recording area, and a unit for determining and recording an inclination angle for obtaining the maximum amplitude value of the reproduction signal, the inclination angle being determined on the basis of the relationship between the detected amplitude value of the reproduction signal and the inclination angle when data is recorded while the inclination angle of the optical axis of light is displaced with respect to the surface of the optical disc, wherein data is recorded while the optical axis of light is inclined by the recorded inclination angle.

An optical disc recording/reproducing apparatus according to claim 18 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting a reading state of address information from the reproduction signal having been generated by reproduction on a recording area, a unit for recording data while displacing the inclination angle of the optical axis of light with respect to the surface of the optical disc, and detecting a reading state of data from the reproduction signal having been generated by reproduction on the recording area, and a unit for determining an inclination angle for obtaining the best reading state of address information and an inclination angle for obtaining the best reading state of data, the inclination angles being determined on the basis of the relationship among the detected reading state of address information, the detected reading state of data, and the inclination angle when data is recorded while the inclination angle of the optical axis of light is displaced with respect to the surface of the optical disc, the unit determining and recording an optimum inclination angle for recording on the basis of the inclination angles, wherein data is recorded while the optical axis of light is inclined by the recorded inclination angle.

An optical disc recording/reproducing apparatus according to claim 19 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting a reading state of data from the reproduction signal having been generated by reproduction on a recording area, a unit for recording data while displacing the inclination angle of the optical axis of light with respect to the surface of the optical disc, and detecting an amplitude value of the reproduction signal having been generated by reproduction on the recording area, and a unit for determining an inclination angle for obtaining the best reading state of data and an inclination angle for obtaining the maximum amplitude value of the reproduction signal, the inclination angles being determined on the basis of the relationship among the detected reading state of data, the detected amplitude value of the reproduction signal, and the inclination angle when data is recorded while the inclination angle of the optical axis of light is displaced with respect to the surface of the optical disc, the unit determining and recording an optimum inclination angle for recording on the basis of the inclination angles, wherein data is recorded while the optical axis of light is inclined by the recorded inclination angle.

An optical disc recording/reproducing apparatus according to claim 20 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for recording data while displacing the inclination angle of the optical axis of light with respect to the surface of the optical disc, and detecting a reading state of address information from the reproduction signal having been generated by reproduction on a recording area, a unit for recording data while displacing the inclination angle of the optical axis of light with respect to the surface of the optical disc, and detecting an amplitude value of the reproduction signal having been generated by reproduction on the recording area, and a unit for determining an inclination angle for obtaining the best reading state of address information and an inclination angle for obtaining the maximum amplitude value of the reproduction signal, the inclination angles being determined on the basis of the relationship among the detected reading state of address information, the detected amplitude value of the reproduction signal, and the inclination angle when data is recorded while the inclination angle of the optical axis of light is displaced with respect to the surface of the optical disc, the unit determining and recording an optimum inclination angle for recording on the basis of the inclination angles, wherein data is recorded while the optical axis of light is inclined by the recorded inclination angle.

An optical disc recording/reproducing apparatus according to claim 21 of the present invention, comprising an optical pickup for emitting light on a track of an optical disc on which address information is recorded beforehand, and outputting a signal according to light reflected from the optical disc, a signal generating unit for generating a reproduction signal on the basis of the output of the optical pickup, and a unit for inclining the optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein the apparatus further comprises a unit for displacing the inclination angle of the optical axis of light with respect to the surface of the optical disc, a unit for detecting a reading state of address information from the reproduction signal having been generated by light reflected from the optical disc when data is recorded while the inclination angle of the optical axis of light is displaced with respect to the surface of the optical disc, and a unit for determining and recording an inclination angle for obtaining the best reading state of address information, the inclination angle being determined on the basis of the relationship between the detected reading state of address information and the inclination angle when data is recorded while the inclination angle of the optical axis of light is displaced with respect to the surface of the optical disc, wherein data is recorded while the optical axis of light is inclined by the recorded inclination angle.

As described above, according to the present invention, the best recording quality can be obtained. Thus, it is possible to obtain a sufficient read margin during reproduction, thereby stably performing recording and reproduction even when recording and reproduction characteristics are somewhat degraded by changes in environment.

### BRIEF DESCRIPTION OF THE DRAWINGS

FIG. 1 is a block diagram showing a structural example of an optical disc recording/reproducing apparatus according to an embodiment of the present invention;

FIG. 2 is a block diagram schematically showing the configuration of a MiniDisc player using a conventional detrack tolerance detector;

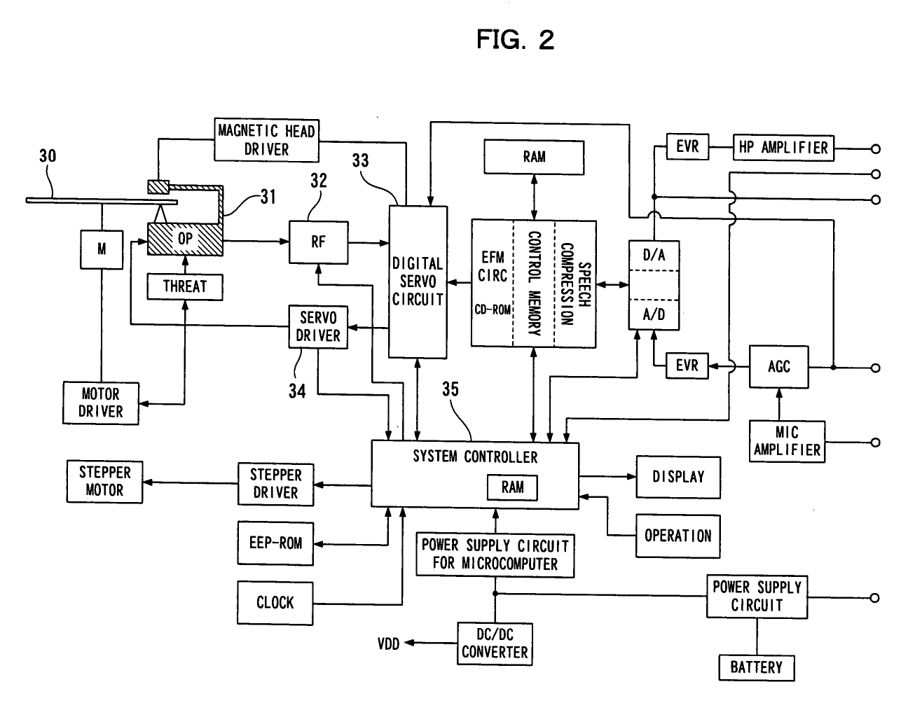

FIG. 3 is a block diagram showing the detail of circuits of an RF amplifier and so on shown in FIG. 2;

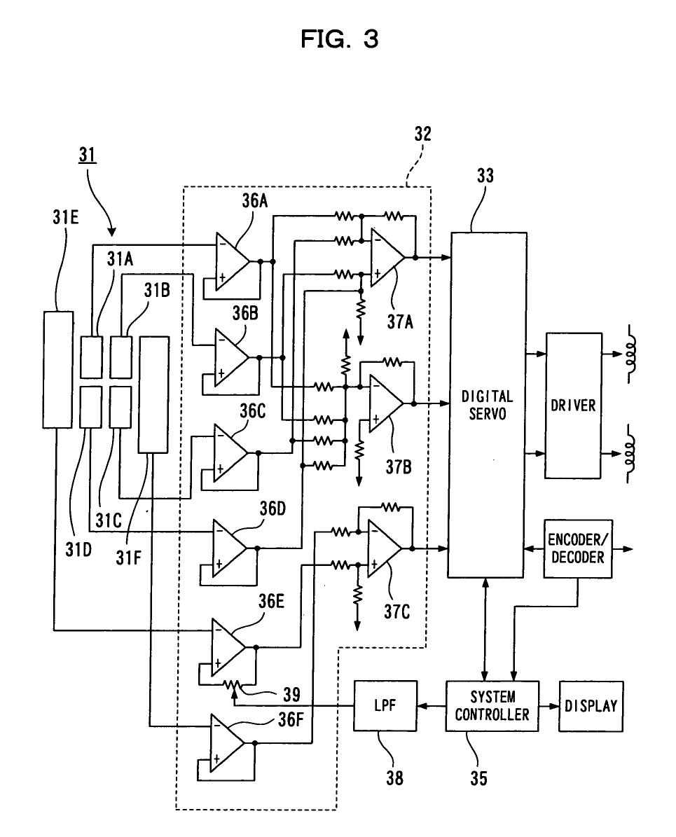

FIG. 4 is a waveform chart showing a tracking error signal where a deviation value is added;

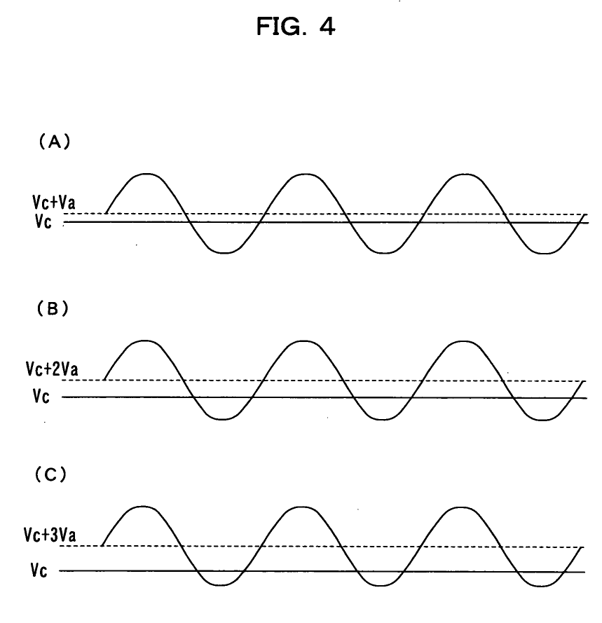

FIG. 5 is a waveform chart showing the tracking error signal where a deviation value is added;

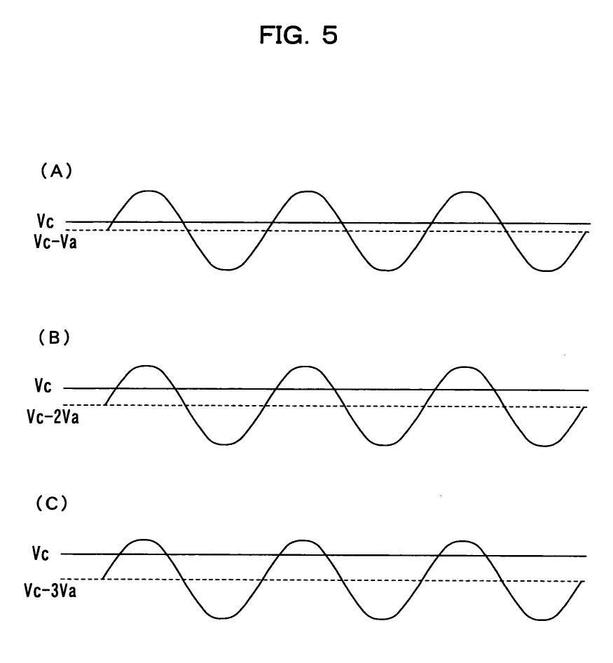

FIG. 6 is a diagram showing an example of the relationship between a detrack value and an address error value;

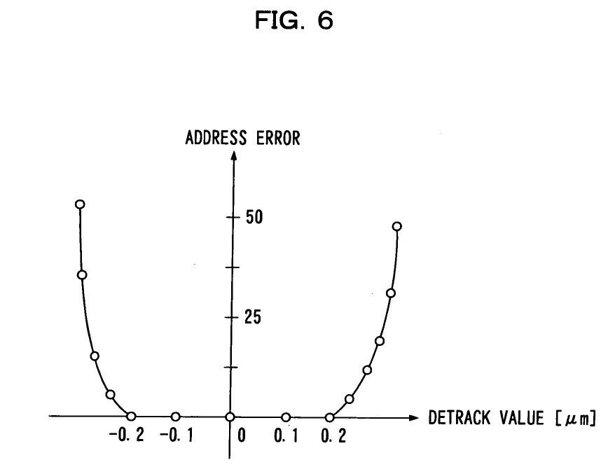

FIG. 7 is a diagram showing an example of the relationship between a detrack value and a jitter value of data obtained by binarizing a reproduction RF signal and the relationship between a detrack value and an address error value; and

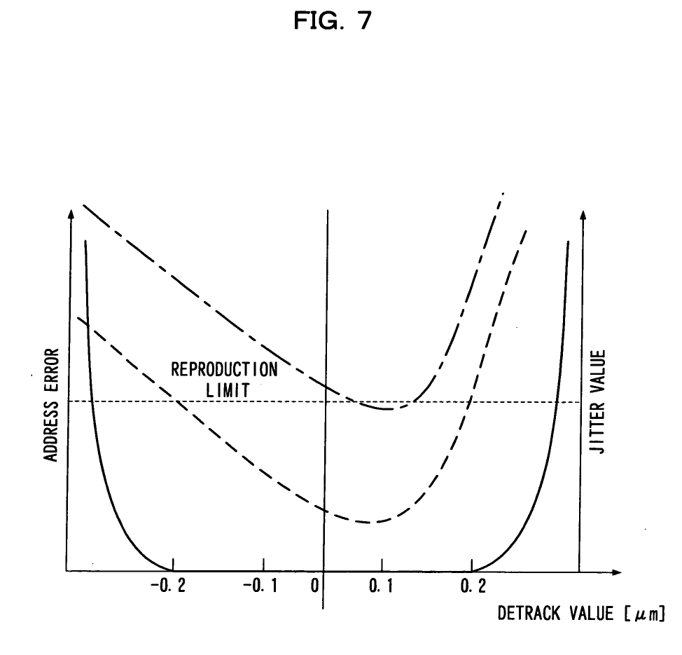

FIG. 8 is a diagram for explaining conventional problems.

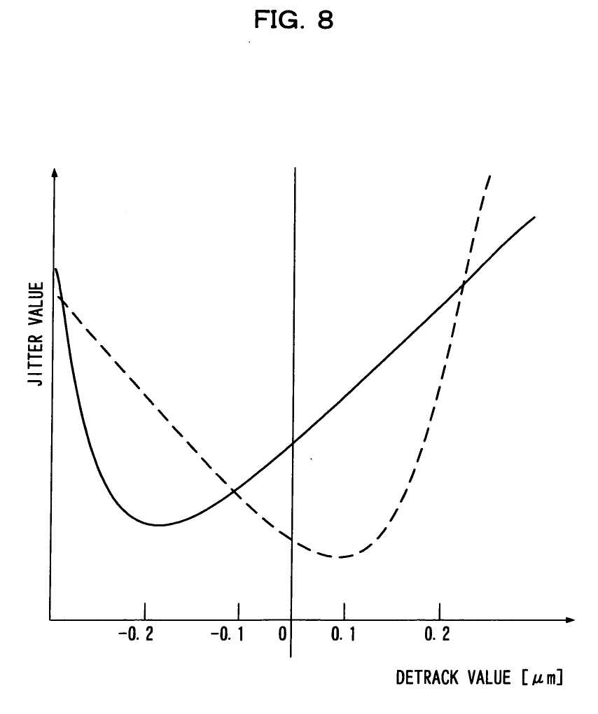

### BEST MODE CARRYING OUT THE INVENTION

An embodiment of the present invention will be described below in accordance with the accompanying drawings. This embodiment is just an example and the present invention is not limited to the embodiment described below.

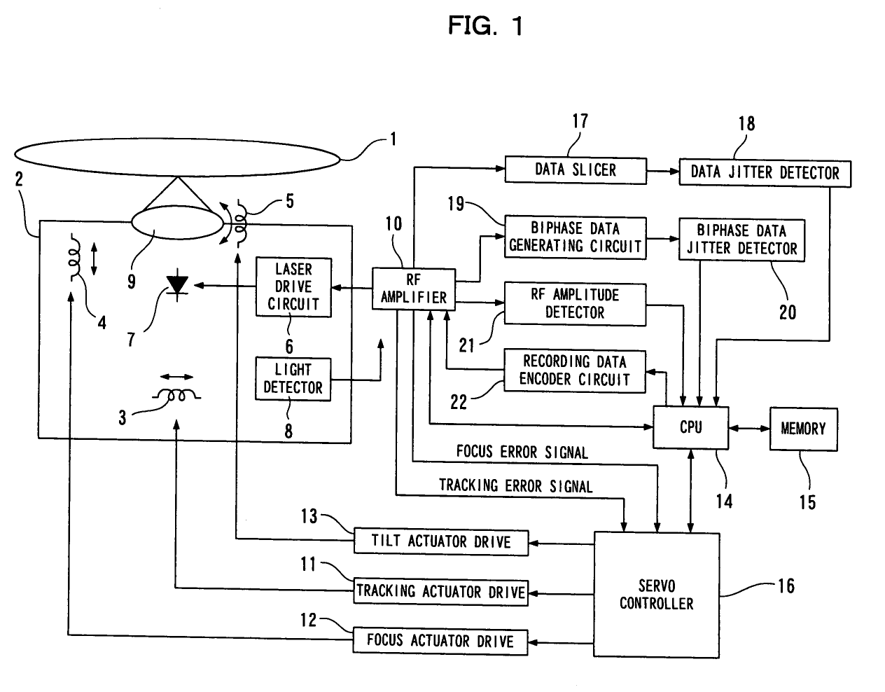

FIG. 1 is a block diagram showing a structural example of an optical disc recording/reproducing apparatus according to the present embodiment. In FIG. 1, reference numeral 1 denotes a recordable optical disc where address information is recorded beforehand, and reference numeral 2 denotes an optical pickup which emits laser light as light to be emitted to the optical disc 1 and outputs a signal according to light reflected from the optical disc 1. The optical pickup 2 is constituted of a tracking actuator 3, a focus actuator 4, a tilt actuator 5, a laser drive circuit 6, a laser diode 7, a light detector 8, and an object lens 9.

The laser drive circuit 6 is controlled by an RF amplifier 10 (described later) and drives the laser diode 7. The laser diode 7 emits laser light with radiation power corresponding to an amount of current supplied by the laser drive circuit 6. The object lens 9 condenses laser light emitted from the laser diode 7 and forms a light spot on the optical disc 1. The tracking actuator 3 moves the object lens 9 in the radius direction (tracking direction) of the disc and adjusts the tracking position of the light spot. The focus actuator 4 moves the object lens 9 in the contacting/separating direction (focus direction) with respect to the disc and adjusts the focus position of-laser light. The tilt actuator 5 changes the angle of the object lens 9 and adjusts the inclination angle of the optical axis of laser light with respect to a surface of the optical disc 1. The light detector 8 receives light reflected from the optical disc 1, converts the light into an electric signal, and outputs the signal.

Reference numeral 10 denotes the RF amplifier which serves as a signal generating unit for generating a tracking error signal according to a deviation from the track center (predetermined tracking position) of a light spot, a focus error signal according to a deviation of the focus of laser light from the surface of the optical disc 1 (focus point), and a reproduction RF signal as a reproduction signal, by arithmetic on the basis of the output signal (electric signal) of the light detector 8. Further, the RF amplifier 10 transmits, to the laser drive circuit 6, a signal generated according to an instruction from a CPU 14 (described later) or a signal corresponding to data inputted from a recording data encoder circuit 22, and controls the on/off of laser output from the laser diode 7 and the radiation power of laser light.

In the following explanation, the predetermined tracking position is initially set at the track center. Needless to say, the predetermined tracking position is not limited to the track center. Although the focus point is initially set on the surface of the optical disc 1 in the following explanation, naturally the focus point is not limited to the surface of the optical disc 1.

Reference numeral 11 denotes a tracking actuator drive for driving the tracking actuator 3, reference numeral 12 denotes a focus actuator drive for driving the focus actuator 4, and reference numeral 13 denotes a tilt actuator drive for driving the tilt actuator 5.

Reference numeral 14 denotes the CPU for controlling the entire apparatus, and reference numeral 15 denotes memory serving as a storage device capable of exchanging data with the CPU 14.

Reference numeral 16 denotes a servo controller which controls the tracking actuator drive 11 according to the tracking error signal to drive the tracking actuator 3 such that a light spot tracks the track center. The servo controller controls the focus actuator drive 12 according to the focus error signal to drive the focus actuator 4 such that laser light is focused on the surface of the optical disc 1. Further, the servo controller controls the tilt actuator drive 13 according to a command from the CPU 14 to drive the tilt actuator 5 such that the light detector 8 efficiently receives reflected light.

Reference numeral 17 denotes a data slicer which binarizes the reproduction RF signal generated by the RF amplifier 10 and converts the signal into data (digital signal). Reference numeral 18 denotes a data jitter detector which outputs to the CPU 14 a signal corresponding to the jitter value of the data.

Reference numeral 19 denotes a biphase data generating circuit which generates biphase data from the reproduction RF signal generated by the RF amplifier 10. On both ends of the track of the optical disc 1, an ATIP signal serving as address information forms waves while being frequency modulated. The reproduction RF signal includes a component having been frequency modulated. The biphase data generating circuit 19 extracts the frequency modulated component, binarizes the component, and performs frequency demodulation on the component, so that biphase data (address data) is generated from the reproduction RF signal. Reference numeral 20 denotes a biphase data jitter detector which outputs to the CPU 14 a signal corresponding to the jitter value of the biphase data.

Reference numeral 21 denotes an RF amplitude detector which detects an amplitude value of the reproduction RF signal generated by the RF amplifier 10 and outputs the amplitude value to the CPU 14.

Reference numeral 22 denotes a recording data encoding circuit which encodes data to be recorded on the optical disc 1 in response to an instruction from the CPU 14 and outputs the data to the RF amplifier 10.

The following will discuss the operations of a tracking servo system of the optical disc recording/reproducing apparatus configured thus.

When current is supplied to the laser diode 7 by the laser drive circuit 6, the laser diode 7 emits laser light with radiation power corresponding to an amount of the current. The laser light is focused at the track center on the surface of the optical disc 1 by the object lens 9 and forms a light spot. Light reflected from the optical disc 1 passes through the object lens 9 again and is received by the light detector 8. The light detector 8 converts the received reflected light into an electric signal and outputs the signal to the RF amplifier 10.

As described above, the RF amplifier 10 generates the tracking error signal according to a deviation from the track center of the light spot on the basis of the electric signal from the light detector 8, and outputs the signal to the servo controller 16. In normal times, the servo controller 16 outputs a tracking control signal (PWM signal), which is generated on the basis of the tracking error signal, to the tracking actuator drive 11. The tracking actuator drive 11 supplies a current corresponding to the tracking control signal to the tracking actuator 3, and moves the object lens 9 in the tracking direction to cause the light spot to track the track center.

The RF amplifier 10 or the servo controller 16 has the function of adding an offset voltage (voltage for increasing or reducing the center voltage value of the tracking error signal) as a deviation value to the tracking error signal. When the CPU 14 instructs the RF amplifier 10 or the servo controller 16 to add the offset voltage to the tracking error signal, the servo controller 16 generates the tracking control signal on the basis of the tracking error signal where the offset voltage is added. The tracking actuator drive 11 supplies a current corresponding to the tracking control signal to the tracking actuator 3, and moves the object lens 9 in the tracking direction to cause the light spot to track a tracking position displaced from the track center according to the offset voltage.

The following will discuss the operations of a focus servo system.

As described above, the RF amplifier 10 generates the focus error signal according to a deviation of the focus of laser light from the surface of the optical disc 1 on the basis of the electric signal outputted from the light detector 8 included in the optical pickup 2, and outputs the signal to the servo controller 16. In normal times, the servo controller 16 outputs a focus control signal (PWM signal), which is generated on the basis of the focus error signal, to the focus actuator drive 12. The focus actuator drive 12 supplies a current corresponding to the focus control signal to the focus actuator 4, and moves the object lens 9 in the focus direction so as to focus laser light on the surface of the optical disc 1.

The RF amplifier 10 or the servo controller 16 has the function of adding an offset voltage (voltage for increasing or reducing the center voltage of the focus error signal) as a deviation value to the focus error signal. When the CPU 14 instructs the RF amplifier 10 or the servo controller 16 to add the offset voltage to the focus error signal, the servo controller 16 generates the focus control signal on the basis of the focus error signal where the offset voltage is added. The focus actuator drive 12 supplies a current corresponding to the focus control signal to the focus actuator 4, and moves the object lens 9 in the focus direction so as to focus laser light on a position displaced from the surface of the optical disc 1 according to the offset voltage.

Tilt control will be discussed below. The servo controller 16 outputs a tilt control signal to the tilt actuator drive 13 in response to an instruction from the CPU 14. The tilt actuator drive 13 supplies a current corresponding to the tilt control signal to the tilt actuator 5. The tilt actuator 5 inclines the object lens 9 by an angle corresponding to an amount of the supplied current.

The recording of data will be discussed below. In response to an instruction from the CPU 14, the recording data encoder circuit 22 encodes data to be recorded on the optical disc 1 and outputs the data to the RF amplifier 10. The RF amplifier 10 sends a signal on the basis of the encoded data to the laser drive circuit 6 included in the optical pickup 2. The laser drive circuit 6 drives the laser diode 7 on the basis of the signal sent from the RF amplifier 10, so that pits are formed on the track of the optical disc 1 according to “0” and “1” of the encoded data.

According to the above description, the following will discuss processing for determining a tracking deviation for obtaining the best reading state of address information in the optical disc recording/reproducing apparatus.

First, while recording data on the optical disc 1, the CPU 14 instructs the RF amplifier 10 or the servo controller 16 to gradually add an offset voltage, which serves as a deviation value, to the tracking error signal. However, as described above, the center voltage value of the tracking error signal is initially set such that a spot (light spot) of laser light condensed by the object lens 9 tracks the track center in the present embodiment.

The RF amplifier 10 or the servo controller 16 gradually adds the offset voltage to the tracking error signal in response to the instruction from the CPU 14. As described above, in the present embodiment, initialization is performed such that a light spot tracks the track center. Thus, by adding the offset voltage to the tracking error signal, the light spot is displaced from the track center and tracking is shifted. Further, an offset voltage value and a tracking deviation are in proportion to each other.

After the offset voltage within a predetermined range is added to the tracking error signal, recording is ended. The offset voltage is added so as to displace the light spot from the track center to the inside and the outside of the optical disc 1.

Thereafter, the offset voltage is added to the tracking error signal to reproduce an area where data is recorded. During reproduction, laser light is emitted with a radiation power for reproduction. For example, the tracking position in the reproduction is the track center which is set initially. Laser light is condensed by the object lens 9 and is emitted to the optical disc 1. Light reflected from the optical disc 1 passes through the object lens 9 again and is incident on the light detector 8. The light detector 8 converts the received reflected light into an electric signal and outputs the signal to the RF amplifier 10. The RF amplifier 10 generates the reproduction RF signal from the electric signal.

In the present embodiment, in order to detect a jitter value of biphase data as a reading state of address information, an ATIP signal (address information) included in the generated reproduction RF signal is converted into biphase data (address data) in the biphase data generating circuit 19 and is inputted to the biphase data jitter detector 20. The biphase data jitter detector 20 detects the jitter value of the biphase data and outputs the value to the CPU 14.

According to a tracking deviation, that is, the offset voltage value added to the tracking error signal and the detected jitter value of the biphase data, the CPU 14 determines an offset voltage value which minimizes the jitter value of the biphase data, and records the offset voltage value in the memory 15.

In this way, in the present embodiment, an offset voltage value is determined which minimizes the jitter value of the biphase data, as a tracking deviation for obtaining the best reading state of address information. As described above, in the present embodiment, initialization is performed such that a light spot tracks the tracks center. Thus, a tracking deviation is equal to a deviation from the track center. Moreover, it is possible to distinguish whether the deviation is made to the inside or the outside.

According to the present embodiment, for example, when products are manufactured in a factory, the above-described processing is performed to record, in the memory, an offset voltage value corresponding to a tracking deviation for obtaining the best reading state of address information. When the product is actually used by the user, the offset voltage value recorded in the memory is added to the tracking error signal to record data. Thus, it is possible to record data with the best reading state of address information, thereby improving the recording quality of the optical disc recording/reproducing apparatus.

The following will discuss processing for determining a tracking deviation for obtaining the best reading state of data in the optical disc recording/reproducing apparatus.

First, as described above, data is recorded while an offset voltage serving as a deviation value is gradually added to the tracking error signal, and then reproduction is performed on the area.

In the present embodiment, in order to detect a jitter value of data as a reading state of the data, the reproduction RF signal is binarized and converted into data in the data slicer 17, and the signal is inputted to the data jitter detector 18. The data jitter detector 18 detects a jitter value of the data and outputs the jitter value to the CPU 14.

According to a tracking deviation, that is, an offset voltage value added to the tracking error signal and a jitter value of the data, the CPU 14 determines an offset voltage value which minimizes the jitter value of the data, and records the offset voltage value in the memory 15.

In this way, in the present embodiment, an offset voltage value where data has the minimum jitter value is determined as a tracking deviation for obtaining the best reading state of recorded data.

According to the present embodiment, for example, when products are manufactured in a factory, the above-described processing is performed to record, in the memory, an offset voltage value corresponding to a tracking deviation for obtaining the best reading state of data. When the product is actually used by the user, the offset voltage value recorded in the memory is added to the tracking error signal to record data. Thus, it is possible to record data with the best reading state of the data, thereby improving the recording quality of the optical disc recording/reproducing apparatus.

The following will discuss processing for determining a tracking deviation which collectively improves the reading state of previously recorded address information and the reading state of recorded data in the optical disc recording/reproducing apparatus. The present embodiment determines a tracking deviation where the reproduction RF signal has the maximum amplitude value.

First, as described above, data is recorded while an offset voltage serving as a deviation value is gradually added to the tracking error signal, and then reproduction is performed on the area.

The reproduction RF signal generated in the RF amplifier 10 is inputted to the RF amplitude detector 21 and the amplitude value of the signal is detected. According to a tracking deviation, that is, an offset voltage value added to the tracking error signal and an amplitude value of the reproduction RF signal detected by the RF amplitude detector 21, the CPU 14 determines an offset voltage value where the reproduction RF signal has the maximum amplitude value, and records the offset voltage value in the memory 15.

In this way, in the present embodiment, an offset voltage value where the reproduction RF signal has the maximum amplitude value is determined as a tracking deviation which collectively improves the reading state of previously recorded address information and the reading state of recorded data.

According to the present embodiment, for example, when products are manufactured in a factory, the above-described processing is performed to record, in the memory, an offset voltage value corresponding to a tracking deviation for obtaining the maximum amplitude value of the reproduction RF signal. When the product is actually used by the user, the offset voltage value recorded in the memory is added to the tracking error signal to record data. Thus, it is possible to record data so as to collectively improve the reading state of previously recorded address information and the reading state of recorded data, thereby improving the recording quality of the optical disc recording/reproducing apparatus.

The above explanation described the determination of the offset voltage value where biphase data has the minimum jitter value, the offset voltage value where data has the minimum jitter value, and the offset voltage value where the reproduction RF signal has the maximum amplitude. As a matter of course, these offset voltage values may be combined to determined an optimum offset voltage value for recording.

For example, the following processing is also applicable: by using the reproduction RF signal generated by reproducing an area where data has been recorded while tracking is displaced, an offset voltage value where biphase data has the minimum jitter value and an offset voltage value where data has the minimum jitter value are determined, and an optimum offset voltage value for recording is determined according to the equation below and is recorded in the memory 15. The optimum offset voltage value collectively improves the reading state of previously recorded address information and the reading state of recorded data.
z=a(x+y)
where x=an offset voltage value where biphase data has the minimum jitter value, y=an offset voltage value where data has the minimum jitter value, z=an optimum offset voltage value for recording, and a value a is set such that z has a value between x and y.

As an offset voltage value corresponding to an optimum tracking deviation for recording that collectively improves the reading state of previously recorded address information and the reading state of recorded data, an offset voltage value may be determined as follows: a difference between the offset voltage value where biphase data has the minimum jitter value and the offset voltage value where data has the minimum jitter value is multiplied by a certain ratio.

The same effect can be obtained also by combining the offset voltage value where data has the minimum jitter value and the offset voltage value where the reproduction RF signal has the maximum amplitude value, and combining the offset voltage value where biphase data has the minimum jitter value and the offset voltage value where the reproduction RF signal has the maximum amplitude value.

The above explanation described processing for recording data while gradually adding a deviation value to the tracking error signal, and then reproducing the area to determine an optimum offset voltage value for recording. Since the jitter value of biphase data can be detected even during data recording, the jitter value of biphase data may be determined during recording.

When data is recorded on the optical disc 1, as described above, pits are formed on the track of the optical disc 1 according to “0” and “1” of the encoded data. That is, during recording, the radiation power of laser light is controlled so as to emit laser light with high radiation power when pits are formed. Laser light is emitted with low radiation power when no pit is formed. The low radiation power is at the same level as the reproduction of data. Thus, the jitter value of biphase data can be detected on the basis of the reproduction RF signal which is obtained when laser light is emitted with the radiation power for reproduction.

In this way, by determining the jitter value of biphase data during recording, it is possible to eliminate the need for reproduction after recording, thereby shortening processing time.

The above explanation described processing for improving the recording quality of the optical disc recording/reproducing apparatus by displacing tracking. Similarly, the recording quality of the optical disc recording/reproducing apparatus may be improved by displacing the focus of laser light from the surface of the optical disc 1 (focus point).

That is, the following processing is also applicable: a deviation value (offset voltage) is gradually added to the focus error signal, data is recorded while the focus of laser light is displaced from the surface of the optical disc 1 (focus point), the area is reproduced to detect the jitter value of biphase data, the jitter value of data, and the amplitude value of the reproduction RF signal, and an offset voltage value where biphase data has the minimum jitter value, an offset voltage value where data has the minimum jitter value, and an offset voltage value where the reproduction RF signal has the maximum amplitude value are determined and recorded. Thus, the recorded offset voltage value is added to the focus error signal and data can be recorded while the focus position of laser light is displaced from the focus point to an optimum position for recording, thereby improving the recording quality of the optical disc recording/reproducing apparatus. As described above, the jitter value of the biphase data can be determined during recording.

Similarly, the recording quality of the optical disc recording/reproducing apparatus can be improved by adjusting an inclination angle (tilt angle) of the optical axis of laser light with respect to the surface of the optical disc 1. That is, the following processing is also applicable: while data is recorded on the optical disc 1, the CPU 14 instructs the servo controller 16 to gradually displace the inclination angle of the optical axis of laser light with respect to the surface of the optical disc 1, the recorded area is reproduced after recording, and a jitter value of biphase data, a jitter value of data, and an amplitude value of the reproduction RF signal are detected, and a tilt angle where the biphase data has the minimum jitter value, a tilt angle where the data has the minimum jitter value, and a tilt angle where the reproduction RF signal has the maximum amplitude value are determined and are recorded in the memory 15 on the basis of the inclination angle provided for the servo controller 16, the detected jitter value of the biphase data, the jitter value of the data, and the amplitude value of the reproduction RF signal. With this processing, during data recording, the optical axis of laser light is inclined so as to have the recorded inclination angle with respect to the surface of the optical disc. Thus, it is possible to efficiently receive reflected light on a photoreceptor, thereby improving the recording quality of the optical disc recording/reproducing apparatus. As described above, the jitter value of biphase data can be determined during recording.

1. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
said apparatus further comprises:
a unit for displacing tracking by supplying a deviation value to the tracking error signal,
a unit for recording data while displacing tracking, and detecting a reading state of address information from the reproduction signal having been generated by reproduction on a recording area, and
a unit for determining and recording a tracking deviation for obtaining a best reading state of address information, the tracking deviation being determined on a basis of a relationship between the detected reading state of address information and a tracking deviation when data is recorded while tracking is displaced, wherein
data is recorded while tracking is displaced by the recorded tracking deviation.

2. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for recording data while displacing tracking, and detecting a reading state of data from the reproduction signal having been generated by reproduction on a recording area, and
a unit for determining and recording a tracking deviation for obtaining a best reading state of data, the tracking deviation being determined on a basis of a relationship between the detected reading state of data and a tracking deviation when data is recorded while tracking is displaced, wherein
data is recorded while tracking is displaced by the recorded tracking deviation.

3. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for recording data while displacing tracking, and detecting an amplitude value of the reproduction signal having been generated by reproduction on a recording area, and
a unit for determining and recording a tracking deviation for obtaining a maximum amplitude value of the reproduction signal, the tracking deviation being determined on a basis of a relationship between the detected amplitude value of the reproduction signal and a tracking deviation when data is recorded while tracking is displaced, wherein
data is recorded while tracking is displaced by the recorded tracking deviation.

4. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for recording data while displacing tracking, and detecting a reading state of address information from the reproduction signal having been generated by reproduction on a recording area,
a unit for recording data while displacing tracking, and detecting a reading state of data from the reproduction signal having been generated by reproduction on the recording area, and
a unit for determining a tracking deviation for obtaining a best reading state of address information and a tracking deviation for obtaining a best reading state of data, the tracking deviations being determined on a basis of a relationship among the detected reading state of address information, the detected reading state of data, and a tracking deviation when data is recorded while tracking is displaced, the unit determining and recording an optimum tracking deviation for recording on a basis of the deviations, wherein
data is recorded while tracking is displaced by the recorded tracking deviation.

5. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for recording data while displacing tracking, and detecting a reading state of data from the reproduction signal having been generated by reproduction on a recording area,
a unit for recording data while displacing tracking, and detecting an amplitude value of the reproduction signal having been generated by reproduction on the recording area, and
a unit which determines a tracking deviation for obtaining a best reading state of data and a tracking deviation for obtaining a maximum amplitude value of the reproduction signal, the tracking deviations being determined on a basis of a relationship among the detected reading state of data, the detected amplitude value of the reproduction signal, and a tracking deviation when data is recorded while tracking is displaced, the unit determining and recording an optimum tracking deviation for recording on a basis of the deviations, wherein
data is recorded while tracking is displaced by the recorded tracking deviation.

6. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for recording data while displacing tracking, and detecting a reading state of address information from the reproduction signal having been generated by reproduction on a recording area,
a unit for recording data while displacing tracking, and detecting an amplitude value of the reproduction signal having been generated by reproduction on the recording area, and
a unit for determining a tracking deviation for obtaining a best reading state of address information and a tracking deviation for obtaining a maximum amplitude value of the reproduction signal, the tracking deviations being determined on a basis of a relationship among the detected reading state of address information, the detected amplitude value of the reproduction signal, and a tracking deviation when data is recorded while tracking is displaced, the unit determining and recording an optimum tracking deviation for recording on a basis of the deviations, wherein
data is recorded while tracking is displaced by the recorded tracking deviation.

7. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a tracking error signal on a basis of an output of the optical pickup, the tracking error signal corresponding to a tracking deviation, the optical disc recording/reproducing apparatus performing tracking according to the tracking error signal to record and reproduce data, wherein
the apparatus further comprises:
a unit for displacing tracking by supplying a deviation value to the tracking error signal,
a unit for detecting a reading state of address information from the reproduction signal having been generated by light reflected from the optical disc when data is recorded with displaced tracking, and
a unit for determining and recording a tracking deviation for obtaining a best reading state of address information, the tracking deviation being determined on a basis of a relationship between the detected reading state of address information and the tracking deviation when data is recorded while tracking is displaced, wherein
data is recorded while tracking is displaced by the recorded tracking deviation.

8. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting a reading state of address information from the reproduction signal having been generated by reproduction on a recording area, and
a unit for determining and recording a deviation from the focus point with a best reading state of address information, the deviation being determined on a basis of a relationship between the detected reading state of address information and a deviation from the focus point when the data is recorded while the focus of light is displaced from the focus point, wherein
data is recorded while the focus of light is displaced from the focus point by the recorded deviation from the focus point.

9. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting a reading state of data from the reproduction signal having been generated by reproduction on a recording area, and
a unit for determining and recording a deviation from the focus point with a best reading state of data, the deviation being determined on a basis of a relationship between the detected reading state of data and the deviation from the focus point when data is recorded while the focus of light is displaced from the focus point, wherein
data is recorded while the focus of light is displaced from the focus point by the recorded deviation from the focus point.

10. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting an amplitude value of the reproduction signal having been generated by reproduction on a recording area, and
a unit for determining and recording a deviation from the focus point with a maximum amplitude value of the reproduction signal, the deviation being determined on a basis of a relationship between the detected amplitude value of the reproduction signal and the deviation from the focus point when data is recorded while the focus of light is displaced from the focus point, wherein
data is recorded while the focus of light is displaced from the focus point by the recorded deviation from the focus point.

11. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting a reading state of address information from the reproduction signal having been generated by reproduction on a recording area,
a unit for recording data while displacing the focus of light from the focus point, and detecting a reading state of data from the reproduction signal having been generated by reproduction on the recording area, and
a unit for determining a deviation from the focus point with a best reading state of address information and a deviation from the focus point with a best reading state of data, the deviations being determined on a basis of a relationship among the detected reading state of address information, the detected reading state of data, and a deviation from the focus point when data is recorded while the focus of light is displaced from the focus point, the unit determining and recording an optimum deviation for recording from the focus point on a basis of the deviations, wherein
data is recorded while the focus of light is displaced from the focus point by the recorded deviation from the focus point.

12. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting a reading state of data from the reproduction signal having been generated by reproduction on a recording area,
a unit for recording data while displacing the focus of light from the focus point, and detecting an amplitude value of the reproduction signal having been generated by reproduction on the recording area, and
a unit for determining a deviation from the focus point with a best reading state of data and a deviation from the focus point with a maximum amplitude value of the reproduction signal, the deviations being determined on a basis of a relationship among the detected reading state of data, the detected amplitude value of the reproduction signal, and a deviation from the focus point when data is recorded while the focus of light is displaced from the focus point, the unit determining and recording an optimum deviation for recording from the focus point on a basis of the deviations, wherein
data is recorded while the focus of light is displaced from the focus point by the recorded deviation from the focus point.

13. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for recording data while displacing the focus of light from the focus point, and detecting a reading state of address information from the reproduction signal having been generated by reproduction on a recording area,
a unit for recording data while displacing the focus of light from the focus point, and detecting an amplitude value of the reproduction signal having been generated by reproduction on the recording area, and
a unit for determining a deviation from the focus point with a best reading state of address information and a deviation from the focus point with a maximum amplitude value of the reproduction signal, the deviations being determined on a basis of a relationship among the detected reading state of data, the detected amplitude value of the reproduction signal, and a deviation from the focus point when data is recorded while the focus of light is displaced from the focus point, the unit determining and recording an optimum deviation for recording from the focus point on a basis of the deviations, wherein
data is recorded while the focus of light is displaced from the focus point by the recorded deviation from the focus point.

14. An optical disc recording/reproducing apparatus, comprising an optical pickup for emitting light on a track of an optical disc on which address information is recorded beforehand, and outputting a signal according to light reflected from the optical disc, and a signal generating unit for generating a reproduction signal and a focus error signal on a basis of an output of the optical pickup, the focus error signal corresponding to a deviation of a focus of emitted light from a focus point, the optical disc recording/reproducing apparatus aligning the focus of light with the focus point according to the focus error signal to record and reproduce data, wherein
the apparatus further comprises:
a unit for displacing the focus of light from the focus point by supplying a deviation value to the focus error signal,
a unit for detecting a reading state of address information from the reproduction signal having been generated by light reflected from the optical disc when data is recorded while the focus of light is displaced from the focus point, and
a unit for determining and recording a deviation from the focus point with a best reading state of address information, the deviation being determined on a basis of a relationship between the detected reading state of address information and the deviation from the focus point when data is recorded while the focus of light is displaced from the focus point, wherein
data is recorded while the focus of light is displaced from the focus point by the recorded deviation from the focus point.

15. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting a reading state of address information from the reproduction signal having been generated by reproduction on a recording area, and
a unit for determining and recording an inclination angle for obtaining a best reading state of address information, the inclination angle being determined on a basis of a relationship between the detected reading state of address information and the inclination angle when data is recorded while the inclination angle of the optical axis of light is displaced with respect to the surface of the optical disc, wherein
data is recorded while the optical axis of light is inclined by the recorded inclination angle.

16. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting a reading state of data from the reproduction signal having been generated by reproduction on a recording area, and
a unit for determining and recording an inclination angle for obtaining a best reading state of data, the inclination angle being determined on a basis of a relationship between the detected reading state of data and the inclination angle when data is recorded while the inclination angle of the optical axis of light is displaced with respect to the surface of the optical disc, wherein
data is recorded while the optical axis of light is inclined by the recorded inclination angle.

17. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting an amplitude value of the reproduction signal having been generated by reproduction on a recording area, and
a unit for determining and recording an inclination angle for obtaining a maximum amplitude value of the reproduction signal, the inclination angle being determined on a basis of a relationship between the detected amplitude value of the reproduction signal and the inclination angle when data is recorded while the inclination angle of the optical axis of light is displaced with respect to the surface of the optical disc, wherein
data is recorded while the optical axis of light is inclined by the recorded inclination angle.

18. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting a reading state of address information from the reproduction signal having been generated by reproduction on a recording area,
a unit for recording data while displacing the inclination angle of the optical axis of light with respect to the surface of the optical disc, and detecting a reading state of data from the reproduction signal having been generated by reproduction on the recording area, and
a unit for determining an inclination angle for obtaining a best reading state of address information and an inclination angle for obtaining a best reading state of data, the inclination angles being determined on a basis of a relationship among the detected reading state of address information, the detected reading state of data, and the inclination angle when data is recorded while the inclination angle of the optical axis of light is displaced with respect to the surface of the optical disc, the unit determining and recording an optimum inclination angle for recording on a basis of the inclination angles, wherein
data is recorded while the optical axis of light is inclined by the recorded inclination angle.

19. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting a reading state of data from the reproduction signal having been generated by reproduction on a recording area,
a unit for recording data while displacing the inclination angle of the optical axis of light with respect to the surface of the optical disc, and detecting an amplitude value of the reproduction signal having been generated by reproduction on the recording area, and
a unit for determining an inclination angle for obtaining a best reading state of data and an inclination angle for obtaining a maximum amplitude value of the reproduction signal, the inclination angles being determined on a basis of a relationship among the detected reading state of data, the detected amplitude value of the reproduction signal, and the inclination angle when data is recorded while the inclination angle of the optical axis of light is displaced with respect to the surface of the optical disc, the unit determining and recording an optimum inclination angle for recording on a basis of the inclination angles, wherein
data is recorded while the optical axis of light is inclined by the recorded inclination angle.

20. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for recording data while displacing the inclination angle of the optical axis of light with respect to the surface of the optical disc, and detecting a reading state of address information from the reproduction signal having been generated by reproduction on a recording area,
a unit for recording data while displacing the inclination angle of the optical axis of light with respect to the surface of the optical disc, and detecting an amplitude value of the reproduction signal having been generated by reproduction on the recording area, and
a unit for determining an inclination angle for obtaining a best reading state of address information and an inclination angle for obtaining a maximum amplitude value of the reproduction signal, the inclination angles being determined on a basis of a relationship among the detected reading state of address information, the detected amplitude value of the reproduction signal, and the inclination angle when data is recorded while the inclination angle of the optical axis of light is displaced with respect to the surface of the optical disc, the unit determining and recording an optimum inclination angle for recording on a basis of the inclination angles, wherein
data is recorded while the optical axis of light is inclined by the recorded inclination angle.

21. An optical disc recording/reproducing apparatus, comprising an optical pickup for emitting light on a track of an optical disc on which address information is recorded beforehand, and outputting a signal according to light reflected from the optical disc, a signal generating unit for generating a reproduction signal on a basis of an output of the optical pickup, and a unit for inclining an optical axis of light emitted to the optical disc and adjusting an inclination angle of the optical axis of light with respect to a surface of the optical disc, the optical disc recording/reproducing apparatus adjusting the inclination angle of the optical axis of light with respect to the surface of the optical disc to record and reproduce data, wherein
the apparatus further comprises:
a unit for displacing the inclination angle of the optical axis of light with respect to the surface of the optical disc,
a unit for detecting a reading state of address information from the reproduction signal having been generated by light reflected from the optical disc when data is recorded while the inclination angle of the optical axis of light is displaced with respect to the surface of the optical disc, and
a unit for determining and recording an inclination angle for obtaining a best reading state of address information, the inclination angle being determined on a basis of a relationship between the detected reading state of address information and the inclination angle when data is recorded while the inclination angle of the optical axis of light is displaced with respect to the surface of the optical disc, wherein
data is recorded while the optical axis of light is inclined by the recorded inclination angle.
